(19) United States
(12) Patent Application Publication
(10) Pub. No.: US 2025/0264360 A1
(43) Pub. Date: Aug. 21, 2025

(54) PHOTOELECTRIC SENSOR ASSEMBLY AND ELECTRONIC DEVICE

(71) Applicant: BOE Technology Group Co., Ltd., Beijing (CN)

(72) Inventors: Xinshe YIN, Beijing (CN); Hui ZHAO, Beijing (CN)

(21) Appl. No.: 18/857,829

(22) PCT Filed: Feb. 18, 2024
(86) PCT No.: PCT/CN2024/077380

§ 371 Date: Oct. 18, 2024

(30) Foreign Application Priority Data
Mar. 31, 2023 (CN) 202310345055.5

(51) Int. Cl. G01J 3/50; H10F 39/18

(52) U.S. Cl. CPC G01J 3/50; H10F 39/182

(57) ABSTRACT

Provided in the embodiments of the present disclosure are a photoelectric sensor assembly and an electronic device. The photoelectric sensor assembly (20) comprises a substrate (201) and at least one photoelectric sensor group located on one side of the substrate (201), wherein the photoelectric sensor group comprises at least two photoelectric sensors; each photoelectric sensor comprises a channel region (203); light rays received by the at least two photoelectric sensors have different colors; and the channel regions (203) of the at least two photoelectric sensors have different sizes.

### CROSS-REFERENCE TO RELATED APPLICATION

The present application is a U.S. National Phase Entry of International Application No. PCT/CN2024/077380 having an international filing date of Feb. 18, 2024, which claims priority to Chinese Patent Application No. 202310345055.5 filed to the CNIPA on Mar. 31, 2023 and entitled “Photoelectric Sensor Assembly and Electronic Device”. Contents of the above-identified applications are incorporated into the present application by reference.

### TECHNICAL FIELD

Embodiments of the present disclosure relate to, but are not limited to, the field of display technology, and particularly relate to a photoelectric sensor assembly and an electronic device.

### BACKGROUND

With the widespread application of AI (Artificial Intelligence) technology in mobile display products, it is necessary to customize customers' applications in specific environments according to users' environments at the time of application, so as to increase users' experience in different environments. With the continuous widespread application, we need to know not only brightness information of the environment, but also the color temperature of the surrounding environment or the like, so as to better provide customers with a better experience.

### SUMMARY

The following is a summary of subject matters described herein in detail. This summary is not intended to limit the protection scope of claims.

In one aspect, an embodiment of the present disclosure provides a photoelectric sensor assembly. The photoelectric sensor assembly includes: a substrate; and at least one photoelectric sensor group located on a side of the substrate. The photoelectric sensor group includes at least two photoelectric sensors, each photoelectric sensor includes a channel region, the at least two photoelectric sensors receive light of different colors, and dimensions of channel regions of the at least two photoelectric sensors are different.

In some exemplary embodiments, the photoelectric sensor further includes a first doped region and a second doped region. The first doped region and the second doped region are located on opposite sides of the channel region in a first direction, and at least one of followings of the channel regions of the at least two photoelectric sensors are different: a length in the first direction, a length in a second direction, and a thickness.

The first direction is different from the second direction, and a plane formed by the first direction and the second direction is parallel to a plane where the substrate is located.

In some exemplary embodiments, the photoelectric sensor group includes a first photoelectric sensor that receives a first color light, a second photoelectric sensor that receives a second color light, a third photoelectric sensor that receives a third color light, and a fourth photoelectric sensor that receives a fourth color light.

The photoelectric sensor assembly further includes a photoresist layer located on a side of the photoelectric sensor group away from the substrate. The photoresist layer includes a light-transmitting pattern, a first photoresist pattern, a second photoresist pattern, and a third photoresist pattern. An orthographic projection of the light-transmitting pattern on the substrate overlaps with an orthographic projection of the first photoelectric sensor on the substrate, an orthographic projection of the first photoresist pattern on the substrate overlaps with an orthographic projection of the second photoelectric sensor on the substrate, an orthographic projection of the second photoresist pattern on the substrate overlaps with an orthographic projection of the third photoelectric sensor on the substrate, and an orthographic projection of the third photoresist pattern on the substrate overlaps with an orthographic projection of the fourth photoelectric sensor on the substrate. The first color light is a light transmitted through a full visible light wavelength band, the second color light is a light transmitted through the first photoresist pattern, the third color light is a light transmitted through the second photoresist pattern, and the fourth color light is a light transmitted through the third photoresist pattern.

In some exemplary embodiments, the first photoelectric sensor includes a first channel region, the second photoelectric sensor includes a second channel region, the third photoelectric sensor includes a third channel region, and the fourth photoelectric sensor includes a fourth channel region. A thickness H_{W} of the first channel region, a thickness H_{R} of the second channel region, a thickness H_{G} of the third channel region and a thickness H_{B} of the fourth channel region are the same. A length L_{W} of the first channel region in a first direction, a length L_{R} of the second channel region in the first direction, a length L_{G} of the third channel region in the first direction, and a length L_{B} of the fourth channel region in the first direction are the same. At least two of a length W_{W} of the first channel region in a second direction, a length W_{R} of the second channel region in the second direction, a length W_{G} of the third channel region in the second direction, and a length W_{B} of the fourth channel region in the second direction are different.

In some exemplary embodiments, following equations are satisfied: W_{W}×T_{W}×EQE_{W}/S=W_{R}×T_{R}×EQE_{R}/S=W_{G}×T_{G}×EQE_{G}/S=W_{B}×T_{B}×EQE_{B}/S.

T_{W} is transmittance of the light-transmitting pattern, T_{R} is transmittance of the first photoresist pattern, T_{G} is transmittance of the second photoresist pattern, T_{B} is transmittance of the third photoresist pattern, EQE_{W}/S is a spectral excitation conversion efficiency per unit area of the first channel region, EQE_{R}/S is a spectral excitation conversion efficiency per unit area of the second channel region, EQE_{G}/S is a spectral excitation conversion efficiency per unit area of the third channel region, and EQE_{B}/S is a spectral excitation conversion efficiency per unit area of the fourth channel region.

In some exemplary embodiments, following equations are satisfied: W_{W}×EQE_{W}=W_{R}×EQE_{R}=W_{G}×EQE_{G}=W_{B}×EQE_{B}.

EQE_{W} is a spectral excitation conversion efficiency of the first channel region, EQE_{R} is a spectral excitation conversion efficiency of the second channel region, EQE_{G} is a spectral excitation conversion efficiency of the third channel region; and EQE_{B} is a spectral excitation conversion efficiency of the fourth channel region.

In some exemplary embodiments, the first photoelectric sensor includes a first channel region, the second photoelectric sensor includes a second channel region, the third photoelectric sensor includes a third channel region, and the fourth photoelectric sensor includes a fourth channel region. A length L_{W} of the first channel region in a first direction, a length L_{R} of the second channel region in the first direction, a length L_{G} of the third channel region in the first direction and a length L_{B} of the fourth channel region in the first direction are the same. A length W_{W} of the first channel region in a second direction, a length W_{R} of the second channel region in the second direction, a length W_{G} of the third channel region in the second direction, and a length W_{B} of the fourth channel region in the second direction are the same. At least two of a thickness H_{W} of the first channel region, a thickness H_{R} of the second channel region, a thickness H_{G} of the third channel region and a thickness H_{B} of the fourth channel region are different.

In some exemplary embodiments, following equations are satisfied: T_{W}×EQE_{W}/S(H_{W})=T_{R}×EQE_{R}/S(H_{R})=T_{G}×EQE_{G}/S(H_{G})=T_{B}×EQE_{B}/S(H_{B}).

T_{W} is a transmittance of the light-transmitting pattern, T_{R} is transmittance of the first photoresist pattern, T_{G} is transmittance of the second photoresist pattern, T_{B} is transmittance of the third photoresist pattern, EQE_{w}/S(H_{W}) is a spectral excitation conversion efficiency per unit area of the first channel region with a thickness of H_{W}; EQE_{R}/S(H_{R}) is a spectral excitation conversion efficiency per unit area of the second channel region with a thickness of H_{R}; EQE_{G}/S(H_{G}) is a spectral excitation conversion efficiency per unit area of the third channel region with a thickness of H_{G}; and EQE_{B}/S(H_{B}) is a spectral excitation conversion efficiency per unit area of the fourth channel region a thickness of H_{B}.

In some exemplary embodiments, following equations are satisfied: EQE_{W}(H_{W})=EQE_{R}(H_{R})=EQE_{G}(H_{G})=EQE_{B}(H_{B}).

EQE_{W}(H_{W}) is a spectral excitation conversion efficiency of the first channel region with a thickness of H_{W}; EQE_{R}(H_{R}) is a spectral excitation conversion efficiency of the second channel region with a thickness of H_{R}; EQE_{G}(H_{G}) is a spectral excitation conversion efficiency of the third channel region with a thickness of H_{G}; and EQE_{B}(H_{B}) is a spectral excitation conversion efficiency of the fourth channel region with a thickness of H_{B}.

In some exemplary embodiments, the photoelectric sensor assembly further includes a first electrode and a second electrode located on a side of the photoelectric sensor away from the substrate. The first electrode is connected to the first doped region, and the second electrode is connected to the second doped region.

In some exemplary embodiments, the photoelectric sensor assembly further includes an insulation layer located between the channel region and the photoresist layer.

In another aspect, an embodiment of the present disclosure provides an electronic device. The electronic device includes the photoelectric sensor assembly of any of the above embodiments.

In the photoelectric sensor assembly provided by the embodiment of the present disclosure, the channel regions of the at least two photoelectric sensors are differentially designed to compensate for differences caused by conversion efficiencies of different photoelectric sensors, so that intensities of the signals output by at least part of the photoelectric sensors in the photoelectric sensor group are basically the same.

Other aspects of the present disclosure may be comprehended after the drawings and the detailed description are read and understood.

### BRIEF DESCRIPTION OF DRAWINGS

Accompanying drawings are intended to provide further understanding of technical solutions of the present disclosure and form a part of the specification, and are used to explain the technical solutions of the present disclosure together with embodiments of the present disclosure, but do not form limitations on the technical solutions of the present disclosure. Shapes and sizes of components in the drawings do not reflect actual scales, and are only intended to schematically illustrate contents of the present disclosure.

FIG. 1 is a schematic top view of a photoelectric sensor assembly.

FIG. 2 is a cross-sectional view at identification A of the photoelectric sensor assembly shown in FIG. 1.

FIG. 3 is a curve graph of a mask light transmittance of the photoelectric sensor assembly shown in FIG. 2.

FIG. 4 is a schematic top view of a photoelectric sensor assembly according to an embodiment of the present disclosure.

FIG. 5 is a cross-sectional view at identification B of the photoelectric sensor assembly shown in FIG. 4.

FIG. 6 is a schematic top view of a photoelectric sensor assembly according to another embodiment of the present disclosure.

FIG. 7 is a cross-sectional view at identification C of the photoelectric sensor assembly shown in FIG. 6.

FIG. 8 is a schematic diagram of a curve of a spectral conversion efficiency of a photoelectric sensor assembly according to an embodiment of the present disclosure.

FIG. 9 is a curve graph of an output signal intensity of a photoelectric sensor assembly.

FIG. 10 is a curve graph of an output signal intensity of a photoelectric sensor assembly according to an embodiment of the present disclosure.

### DETAILED DESCRIPTION

Embodiments of the present disclosure will be described in detail hereinafter with reference to the drawings. Implementations may be implemented in a plurality of different forms. Those of ordinary skills in the art may easily understand such a fact that implementations and contents may be transformed into one or more forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, an implementation of the present disclosure is not always limited to the dimension, and the shape and size of each component in the drawings do not reflect an actual scale. In addition, the accompanying drawings schematically illustrate ideal examples, and an implementation of the present disclosure is not limited to shapes, numerical values, or the like shown in the drawings.

Ordinal numerals such as “first”, “second” and “third” in the present disclosure are set to avoid confusion between constituent elements, but not intended for restriction in quantity. In the present disclosure, “a plurality of/multiple” means two or more than two.

In the present disclosure, for convenience, wordings indicating orientation or positional relationship such as “middle”, “upper”, “lower”, “front”, “rear”, “vertical”, “horizontal”, “top”, “bottom”, “inner” and “outer” are employed to explain positional relationship between the constituent elements with reference to the accompanying drawings, they are employed for ease of description of the specification and simplification of the description only, but do not indicate or imply that the referred apparatus or element must have a particular orientation, or is constructed and operate in a particular orientation, and therefore cannot be construed as limitations on the present disclosure. The positional relationships between the constituent elements are changed as appropriate based on directions according to which the constituent elements are described. Therefore, appropriate replacements based on situations are allowed, which is not limited to the expressions in the specification.

In the present disclosure, the terms “mounting”, “coupling” and “connection” are to be understood broadly, unless otherwise expressly specified and defined. For example, it may be a fixed connection, a detachable connection, or an integral connection; it may be a mechanical connection or a connection; it may be a direct connection, an indirect connection through a middleware, or an internal communication between two elements. Those of ordinary skills in the art may understand meanings of the aforementioned terms in the present disclosure according to situations.

In the present disclosure, a transistor refers to an element including at least three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. In the present disclosure, the channel region refers to a region through which a current mainly flows.

In the present disclosure, a first pole may be a drain electrode and a second pole may be a source electrode, or a first pole may be a source electrode and a second pole may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the present disclosure.

In the present disclosure, “connection” includes a case where constituent elements are connected through an element with a certain electrical action. An “element with a certain electrical action” is not particularly limited as long as electrical signals between the connected constituent elements may be sent and received. Examples of the “element with a certain electrical action” not only include electrodes and wirings, but also include switching elements such as transistors, resistors, inductors, capacitors, other elements with one or more functions, etc.

In the present disclosure, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 10°, and thus may include a state in which the angle is above 85° and below 95°.

In the present disclosure, “film” and “layer” are interchangeable. For example, a “conductive layer” may be replaced with a “conductive film” sometimes. Similarly, an “insulation film” may be replaced with an “insulation layer” sometimes.

In the present disclosure, “about” means that a boundary is not defined so strictly and numerical values within a range of process and measurement errors are allowed.

With the widespread application of AI technology, photoelectric sensors not only need to sense the brightness of ambient light, but also need to sense the color temperature information of ambient light, and need to convert ambient light into the three primary color information of the environment.

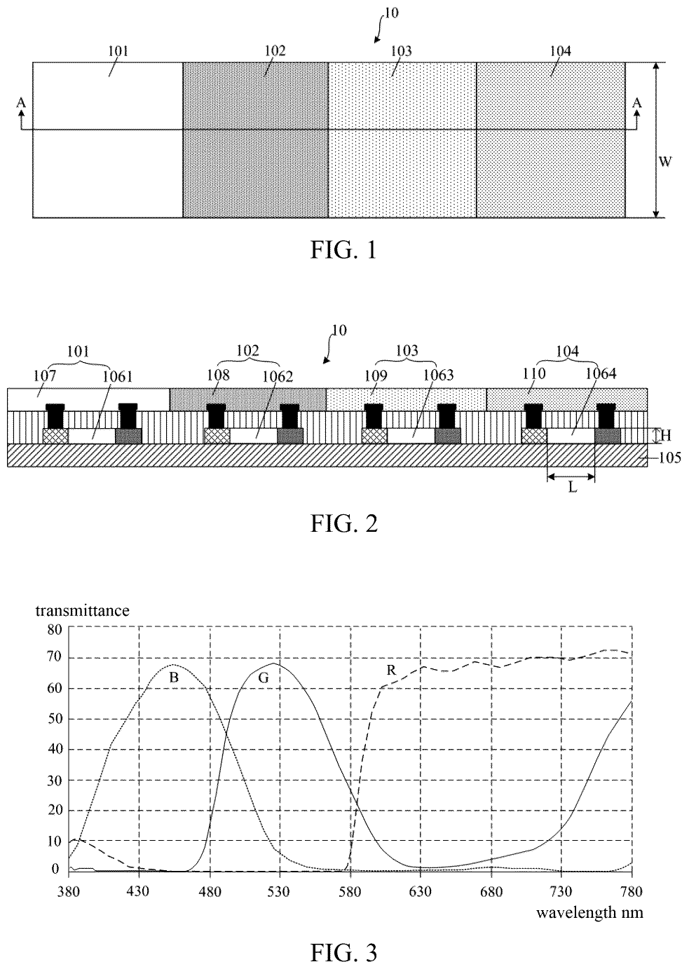

FIG. 1 is a schematic top view of a photoelectric sensor assembly. As shown in FIG. 1, a photoelectric sensor assembly 10 includes a white light sensor 101, a red light sensor 102, a green light sensor 103, and a blue light sensor 104.

FIG. 2 is a cross-sectional view at identification A of the photoelectric sensor assembly shown in FIG. 1. As shown in FIG. 2, each sensor includes a substrate 105, a photodiode disposed on the substrate 105, and a photoresist layer disposed on a side of the photodiode away from the substrate 105. The white light sensor 101 includes a first photodiode 1061 and a first photoresist layer 107, and the first photoresist layer 107 is a transparent thin film and configured to allow all visible light to be transmitted to the first photodiode 1061. The red light sensor 102 includes a second photodiode 1062 and a second photoresist layer 108, and the second photoresist layer 108 is configured to allow only visible light in a red wavelength band to be transmitted to the second photodiode 1062 and prevent visible light other than the red wavelength band from being transmitted, so that the second photodiode 1062 can only sense red light information in ambient light. The green light sensor 103 includes a third photodiode 1063 and a third photoresist layer 109, and the third photoresist layer 109 is configured to allow only visible light in a green wavelength band to be transmitted to the third photodiode 1063 and prevent visible light other than the green wavelength band from being transmitted, so that the third photodiode 1063 can only sense green light information in ambient light. The blue light sensor 104 includes a fourth photodiode 1064 and a fourth photoresist layer 110, and the fourth photoresist layer 110 is configured to allow only visible light in a blue wavelength band to be transmitted to the fourth photodiode 1064 and prevent visible light other than the blue wavelength band from being transmitted, so that the fourth photodiode 1064 can only sense blue light information in ambient light.

The photodiode has a channel length of L (as shown in FIG. 2), a width of W (as shown in FIG. 1), and a thickness of H (as shown in FIG. 2). The photodiode may be a PIN-PD (PIN Photodiode). The same dimension of the photodiodes in each photoelectric sensor makes it impossible to compensate for the difference in output of the photoelectric sensors due to the difference in transmittance of the photoresist patterns and the difference in conversion efficiencies of the photodiodes to different wavelength spectra.

FIG. 3 is a curve graph of a mask light transmittance of the photoelectric sensor assembly shown in FIG. 2. In FIG. 3, the abscissa represents the wavelength of light. The ordinate represents the transmittance of light. In FIG. 3, the curve B represents the transmittance of light passing through the fourth photoresist layer 110, and the curve G represents the transmittance of light passing through the third photoresist layer 109. The curve R represents the transmittance of light passing through the second photoresist layer 108. The transmittance of the first photoresist layer 107 is 100%.

An embodiment of the present disclosure provides a photoelectric sensor assembly. The photoelectric sensor assembly includes: a substrate; and at least one photoelectric sensor group located on a side of the substrate. The photoelectric sensor group includes at least two photoelectric sensors, each photoelectric sensor includes a channel region, the at least two photoelectric sensors receive light of different colors, and dimensions of the channel regions of the at least two photoelectric sensors are different.

In the photoelectric sensor assembly in the embodiment of the present disclosure, the channel regions of the at least two photoelectric sensors are differentially designed to compensate for differences caused by conversion efficiencies of different photoelectric sensors, so that intensities of signals output by at least part of the photoelectric sensors in the photoelectric sensor group are basically the same.

The technical solutions of the embodiments of the present disclosure will be illustrated below by the embodiments.

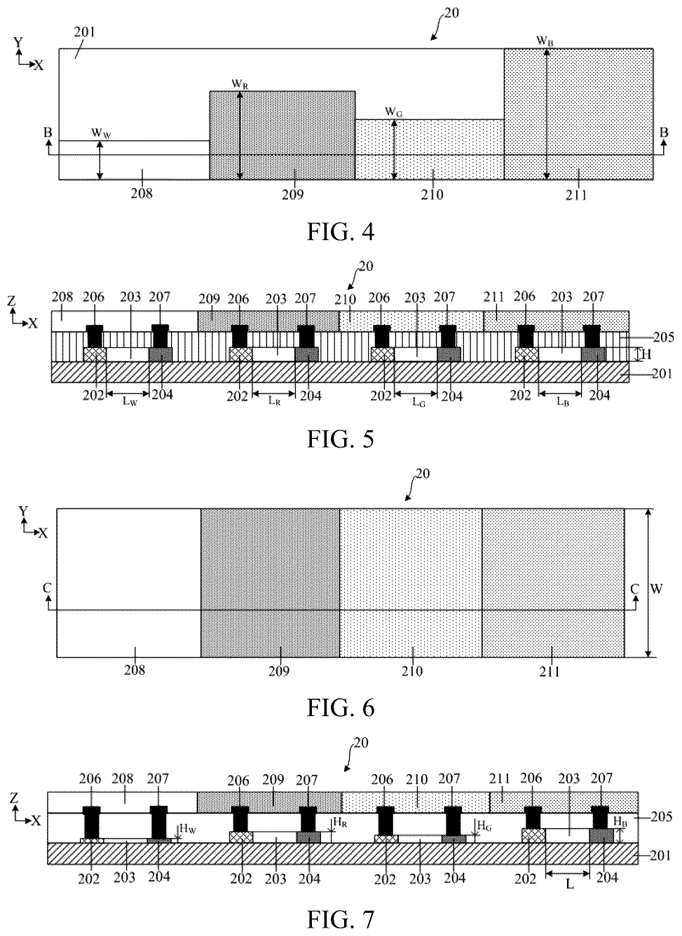

FIG. 4 is a schematic top view of a photoelectric sensor assembly according to an embodiment of the present disclosure. As shown in FIG. 4, three directions are defined for explanation of the technical solution, and a first direction is identified as X, a second direction is identified as Y, and a third direction is identified as Z (as shown in FIG. 5). The first direction, the second direction, and the third direction intersect with each other. In the embodiment of the present disclosure, any two of the first direction, the second direction and a third direction are perpendicular to each other. The third direction (Z) is a thickness direction of a photoelectric sensor assembly 20.

As shown in FIG. 4, the photoelectric sensor assembly 20 may include a substrate 201, a photoelectric sensor group disposed on the substrate 201, and a photoresist layer located on a side of the photoelectric sensor group away from the substrate. The photoelectric sensor group includes at least two photoelectric sensors, each photoelectric sensor includes a channel region 203 disposed on the substrate 201, the at least two photoelectric sensors receive light of different colors, and the dimensions of the channel regions of the at least two photoelectric sensors are different.

In an exemplary embodiment, an orthographic projection of the photoresist layer on the substrate 201 overlaps with orthographic projections of the photoelectric sensors on the substrate 201, and the photoresist layer may filter light to allow light of specific wavelength bands to be incident on the photoelectric sensor.

In an exemplary embodiment, a plane formed by XY is parallel to a plane where the substrate 201 is located. An orthographic projection of the substrate 201 on the plane formed by XY may be a rectangle.

In an exemplary embodiment, the substrate 201 may serve as a carrier for other components of the photoelectric sensor assembly 20 other than the substrate 201. The material of the substrate 201 may be soda-lime glass, quartz glass, sapphire, or the like. For example, the substrate 201 may be a silicon substrate commonly used in the field of semiconductor manufacturing, and the silicon substrate may be a silicon substrate that has not been processed by a semiconductor process, or a silicon substrate that has been processed by a semiconductor process. For example, the silicon substrate may be a silicon substrate processed by a process such as ion implantation, etching, or diffusion, the material of the substrate and the processing process adopted for the substrate are not limited in the present disclosure.

FIG. 5 is a cross-sectional view at identification B of the photoelectric sensor assembly shown in FIG. 4. As shown in FIG. 5, the photoelectric sensor further includes a first doped region 202 and a second doped region 204. The first doped region 202, the channel region 203, and the second doped region 204 constitute a semiconductor junction having a longitudinal structure or a transverse structure. In the embodiment of the present application, a semiconductor junction having a transverse structure is taken as an example. That is, the first doped region 202, the channel region 203, and the second doped region 204 in the semiconductor junction may be arranged along the first direction, and the first doped region 202 and the second doped region 204 are located on opposite sides of the channel region 203 in the first direction.

In an exemplary embodiment, the first doped region 202, the channel region 203, and the second doped region 204 may form a PIN photodiode, which includes a layer of lightly doped N-type material, called I (Intrinsic) layer, between P-type and N-type with high doping concentrations. Because it is lightly doped, the electron concentration is very low, and a wide depletion layer is formed after diffusion. The PIN photodiode has a small dark current and strong response ability to light, which makes the sensor as a whole have a higher signal-to-noise ratio and higher detection efficiency.

In an exemplary embodiment, the photoelectric sensor assembly 20 may further include a first electrode 206 and a second electrode 207 located on a side of the photoelectric sensor away from the substrate 201. The first electrode 206 and the second electrode 207 are arranged in groups. The first electrode 206 is connected to the first doped region 202. The second electrode 207 is connected to the second doped region 204. One of the first electrode 206 and the second electrode 207 may be a positive electrode, and the other of the first electrode 206 and the second electrode 207 may be a negative electrode.

In an exemplary embodiment, the first electrode 206 and the second electrode 207 may be made of a metal material or a transparent conductive material. The metal material may include any one or more of silver (Ag), copper (Cu), aluminum (Al), titanium (Ti), and molybdenum (Mo). Alternatively, both the first electrode 206 and the second electrode 207 may include an alloy material of metal materials such as silver (Ag), copper (Cu), aluminum (Al), titanium (Ti), and molybdenum (Mo). The transparent conductive material may include Indium Tin Oxide (ITO) or Indium Zinc Oxide (IZO).

In an exemplary embodiment, both the first electrode 206 and the second electrode 207 may be a single-layer structure, or a multi-layer composite structure, such as Mo/Cu/Mo or ITO/Al/ITO, or the like.

In an exemplary embodiment, as shown in FIG. 5, the photoelectric sensor assembly 20 may further include an insulation layer 205 located between the channel region 203 and the first electrode 206 and the second electrode 207, and the insulation layer 205 covers the first doped region 202, the channel region 203, and the second doped region 204. The insulation layer 205 is provided with a first through hole and a second through hole, and the first electrode 206 is connected to the first doped region 202 via the first through hole. The second electrode 207 is connected to the second doped region 204 via the second through hole.

In an exemplary embodiment, the material of the insulation layer 205 may be an inorganic material. The inorganic material may include any one or more of silicon oxynitride (SiOₓN_{y}), silicon nitride (SiN), silicon oxide (SiO), silicon dioxide (SiO₂), aluminum oxide (Al₂O₃), titanium dioxide (TiO₂), niobium pentoxide (Nb₂O₅) and the like.

In an exemplary embodiment, the material of the insulation layer 205 may be an organic material. The organic material may include one of polymers such as polyimide (PI), polyacrylate, polyphenylene sulfide, polyarylester, cellulose acetate propionate, polyethylene naphthalate (PEN), polyethylene terephthalate (PET), polyethersulfone resin (PES), polycarbonate (PC), polyetherimide (PEI), cycloolefin polymer (COP), silica gel resin, polyaryl compound (PAR) or glass fiber reinforced plastic (FRP), or a mixture of a plurality of polymers.

In an exemplary embodiment, the insulation layer 205 may be provided as a single-layer film layer, or a composite film layer, or the like.

In an embodiment of the present disclosure, as shown in FIG. 5, the photoelectric sensor group includes a first photoelectric sensor, a second photoelectric sensor, a third photoelectric sensor, and a fourth photoelectric sensor, and the first photoelectric sensor, the second photoelectric sensor, the third photoelectric sensor, and the fourth photoelectric sensor are arranged at intervals along the first direction. The first photoelectric sensor is configured to receive a first color light. For example, the wavelength band of the first color light may be 380 nanometers to 780 nanometers. The second photoelectric sensor is configured to receive a second color light. For example, a center wavelength of the second color light is about 650 nanometers. The third photoelectric sensor is configured to receive a third color light. For example, a center wavelength of the third color light is about 530 nanometers. The fourth photoelectric sensor is configured to receive a fourth color light. For example, a center wavelength of the fourth color light is about 450 nanometers.

FIG. 5 only shows an arrangement form of the first photoelectric sensor, the second photoelectric sensor, the third photoelectric sensor, and the fourth photoelectric sensor, and the arrangement form of at least two photoelectric sensors is not limited in the present disclosure.

In an exemplary embodiment, as shown in FIG. 5, the photoresist layer may include a plurality of photoresist patterns, orthographic projections of the photoresist patterns on the substrate 201 overlap with the orthographic projections of the photoelectric sensor on the substrate 201. The photoresist patterns are configured to allow light of a specific wavelength band to be incident on the photoelectric sensor corresponding thereto.

As shown in FIG. 5, the photoresist layer may include a light-transmitting pattern 208, a first photoresist pattern 209, a second photoresist pattern 210, and a third photoresist pattern 211 disposed in sequence along the first direction.

In an exemplary embodiment, the light-transmitting pattern 208 is configured to allow light in the visible light wavelength band to be incident on the first photoelectric sensor. The light-transmitting pattern 208 does not filter visible light so that all of the visible light is incident on the first photoelectric sensor, and the light-transmitting pattern 208 and the first photoelectric sensor may collectively constitute a white light sensor.

In an exemplary embodiment, as shown in FIG. 5, an orthographic projection of the light-transmitting pattern 208 on the substrate 201 may at least partially overlap with an orthographic projection of the first photoelectric sensor on the substrate 201. For example, the orthographic projection of the light-transmitting pattern 208 on the substrate 201 may cover the orthographic projection of the first photoelectric sensor on the substrate 201. For example, the orthographic projection of the light-transmitting pattern 208 on the substrate 201 may overlap with the orthographic projection of the first photoelectric sensor on the substrate 201, or the like.

In an exemplary embodiment, in the plane constituted by XY, an orthographic projection of the first photoresist pattern 209 overlaps with an orthographic projection of the second photoelectric sensor, and the first photoresist pattern 209 is configured to allow light in the red wavelength band to be incident on the second photoelectric sensor. The first photoresist pattern may filter light other than red light such that all of the red light is incident on the second photoelectric sensor. The first photoresist pattern 209 and the second photoelectric sensor may collectively constitute a red light sensor.

In an exemplary embodiment, the orthographic projection of the first photoresist pattern 209 on the substrate 201 may cover the orthographic projection of the second photoelectric sensor on the substrate 201. Alternatively, the orthographic projection of the first photoresist pattern 209 on the substrate 201 may completely overlap with the orthographic projection of the second photoelectric sensor on the substrate 201.

In an exemplary embodiment, in the plane constituted by XY, an orthographic projection of the second photoresist pattern 210 overlaps with the orthographic projection of a third photoelectric sensor, and the second photoresist pattern 210 is configured to allow light in the green wavelength band to be incident on the third photoelectric sensor. The second photoresist pattern 210 may filter light other than green light such that all of the green light is incident on the third photoelectric sensor. The second photoresist pattern 210 and the third photoelectric sensor may collectively constitute a green light sensor.

In an exemplary embodiment, the orthographic projection of the second photoresist pattern 210 on the substrate 201 may cover the orthographic projection of the third photoelectric sensor on the substrate 201. Alternatively, the orthographic projection of the second photoresist pattern 210 on the substrate 201 may completely overlap with the orthographic projection of the third photoelectric sensor on the substrate 201.

In an exemplary embodiment, in the plane constituted by XY, an orthographic projection of the third photoresist pattern 211 overlaps with an orthographic projection of the fourth photoelectric sensor, and the third photoresist pattern 211 is configured to allow light in the blue wavelength band to be incident on the fourth photoelectric sensor. The third photoresist pattern 211 may filter light other than blue light such that all of the blue light is incident on the fourth photoelectric sensor. The third photoresist pattern 211 and the fourth photoelectric sensor may collectively constitute a blue light sensor.

In an exemplary embodiment, the orthographic projection of the third photoresist pattern 211 on the substrate 201 may cover the orthographic projection of the fourth photoelectric sensor on the substrate 201. Alternatively, the orthographic projection of the third photoresist pattern 211 on the substrate 201 may completely overlap with the orthographic projection of the fourth photoelectric sensor on the substrate 201.

In an exemplary embodiment, at least one of the followings of the channel regions 203 of the at least two photoelectric sensors are different: dimensions along the first direction, dimensions along the second direction, and dimensions along the third direction, so as to achieve a compensation design such that the intensities of the signals output by the at least two photoelectric sensors in the photoelectric sensor group are approximately the same.

In an embodiment of the present disclosure, the channel region 203 included in the first photoelectric sensor is denoted as a first channel region. The channel region 203 included in the second photoelectric sensor is denoted as a second channel region. The channel region 203 included in the third photoelectric sensor is denoted as a third channel region. The channel region 203 included in the fourth photoelectric sensor is denoted as a fourth channel region. In an embodiment of the present disclosure, the first channel region, the second channel region, the third channel region, and the fourth channel region are no longer separately labeled.

In an exemplary embodiment, as shown in FIG. 5, a length L_{W} of the first channel region in the first direction, a length L_{R} of the second channel region in the first direction, a length L_{G} of the third channel region in the first direction and the length L_{B} of the fourth channel region in the first direction are the same. A thickness H_{W} of the first channel region, a thickness H_{R} of the second channel region, a thickness H_{G} of the third channel region and a thickness H_{B} of the fourth channel region are the same, and H_{W}, H_{R}, H_{G}, and H_{B} not separately labeled but labeled as H in FIG. 5.

In an exemplary embodiment, as shown in FIG. 4, a length W_{W} of the first channel region in the second direction is less than a length W_{G} of the third channel region in the second direction, the length W_{G} of the third channel region in the second direction is less than a length W_{R} of the second channel region in the second direction, the length W_{R} of the second channel region in the second direction is less than a length W_{B} of the fourth channel region in the second direction.

In an exemplary embodiment, a length W_{W} of the first channel region in the second direction is less than a length W_{G} of the third channel region in the second direction and a length W_{R} of the second channel region in the second direction, and the length W_{G} of the third channel region in the second direction and the length W_{R} of the second channel region in the second direction are less than a length W_{B} of the fourth channel region in the second direction.

In an exemplary embodiment, as shown in FIG. 4, W_{W}, W_{R}, W_{G} and W_{B} are differentially designed to adjust the photodiode to achieve compensation for ambient light. W_{W}, W_{R}, W_{G} and W_{B} may satisfy the following equations:

$${W}_{W} \times {T}_{W} \times {EQE}_{W} / S = {W}_{R} \times {T}_{R} \times {EQE}_{R} / S = {W}_{G} \times {T}_{G} \times {EQE}_{G} / S = {W}_{B} \times {T}_{B} \times {EQE}_{B} / S .$$

T_{W} is transmittance of the light-transmitting pattern and is 100%; T_{R} is transmittance of the first photoresist pattern, T_{R}=∫₃₀₀⁷⁸⁰T_{R}(λ)d_{λ}; T_{G} is transmittance of the second photoresist pattern, T_{G}=∫₃₀₀⁷⁸⁰T_{G}(λ)d_{λ}; T_{B} is transmittance of the third photoresist pattern, T_{B}=∫₃₀₀⁷⁸⁰T_{B}(λ)d_{λ}.

EQE_{W}/S is a spectral excitation conversion efficiency per unit area of the first channel region, EQE_{R}/S is a spectral excitation conversion efficiency per unit area of the second channel region, EQE_{G}/S is a spectral excitation conversion efficiency per unit area of the third channel region, EQE_{B}/S is a spectral excitation conversion efficiency per unit area of the fourth channel region.

Herein,

$${EQE}_{W} / S = {\int }_{300}^{780} {EQE}_{W} ( λ ) {d}_{λ} / S , {EQE}_{R} / S = {\int }_{300}^{780} {EQE}_{R} ( λ ) {d}_{λ} / S , {EQE}_{G} / S = {\int }_{300}^{780} {EQE}_{G} ( λ ) {d}_{λ} / S , {EQE}_{B} / S = {\int }_{300}^{780} {EQE}_{B} ( λ ) {d}_{λ} / S .$$

In an exemplary embodiment, W_{W}, W_{R}, W_{G} and W_{B} may satisfy the following equation: W_{W}×EQE_{W}=W_{R}×EQE_{R}=W_{G}×EQE_{G}=W_{B}×EQE_{B}, so as to differentially design W_{W}, W_{R}, W_{G} and W_{B}.

EQE_{W} is a spectral excitation conversion efficiency of the first channel region, EQE_{R} is a spectral excitation conversion efficiency of the second channel region, EQE_{G} is a spectral excitation conversion efficiency of the third channel region; EQE_{B} is a spectral excitation conversion efficiency of the fourth channel region.

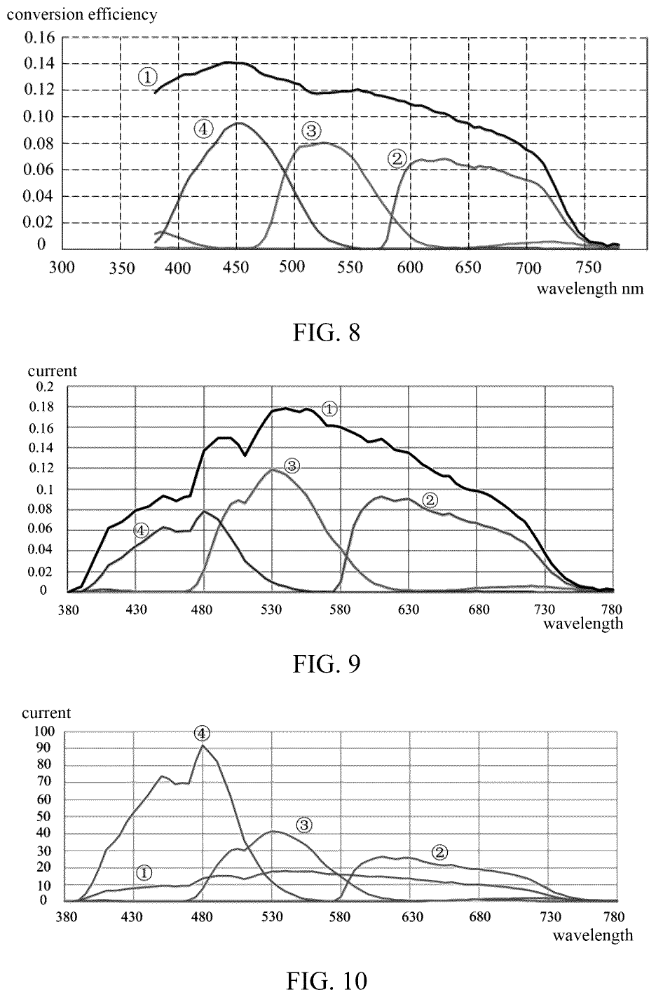

As shown in FIG. 8, curve \textcircled{1} in FIG. 8 is a curve of the spectral excitation conversion efficiency of the first channel region versus the wavelength of incident light; curve \textcircled{2} in FIG. 8 is a curve of the spectral excitation conversion efficiency of the second channel region versus the wavelength of incident light; curve \textcircled{3} in FIG. 8 is a curve of the spectral excitation conversion efficiency of the third channel region versus the wavelength of incident light; and curve \textcircled{4} in FIG. 8 is a curve of the spectral excitation conversion efficiency of the fourth channel region versus the wavelength of incident light.

FIG. 6 is a schematic top view of a photoelectric sensor assembly according to another embodiment of the present disclosure. FIG. 6 and FIG. 4 are schematic top views of photoelectric sensor assemblies according to different embodiments of the present disclosure. As shown in FIG. 6, orthographic projections of the light-transmitting pattern 208, the first photoresist pattern 209, the second photoresist pattern 210, and the third photoresist pattern 211 on the substrate 201 may all have a rectangular shape.

As shown in FIG. 6, the orthographic projection of the light-transmitting pattern 208 on the substrate 201 may at least partially overlap with an orthographic projection of the first photoelectric sensor on the substrate 201. For example, the orthographic projection of the light-transmitting pattern 208 on the substrate 201 may cover the orthographic projection of the first photoelectric sensor on the substrate 201. For example, the orthographic projection of the light-transmitting pattern 208 on the substrate 201 may overlap with the orthographic projection of the first photoelectric sensor on the substrate 201, or the like.

As shown in FIG. 6, the orthographic projection of the first photoresist pattern 209 on the substrate 201 may at least partially overlap with an orthographic projection of the second photoelectric sensor on the substrate 201. For example, the orthographic projection of the first photoresist pattern 209 on the substrate 201 may cover the orthographic projection of the second photoelectric sensor on the substrate 201. For example, the orthographic projection of the first photoresist pattern 209 on the substrate 201 may overlap with the orthographic projection of the second photoelectric sensor on the substrate 201, or the like.

As shown in FIG. 6, the orthographic projection of the second photoresist pattern 210 on the substrate 201 may at least partially overlap with an orthographic projection of the third photoelectric sensor on the substrate 201. For example, the orthographic projection of the second photoresist pattern 210 on the substrate 201 may cover the orthographic projection of the third photoelectric sensor on the substrate 201. For example, the orthographic projection of the second photoresist pattern 210 on the substrate 201 may overlap with the orthographic projection of the third photoelectric sensor on the substrate 201, or the like.

As shown in FIG. 6, the orthographic projection of the third photoresist pattern 211 on the substrate 201 may at least partially overlap with an orthographic projection of the fourth photoelectric sensor on the substrate 201. For example, the orthographic projection of the third photoresist pattern 211 on the substrate 201 may cover the orthographic projection of the fourth photoelectric sensor on the substrate 201. For example, the orthographic projection of the third photoresist pattern 211 on the substrate 201 may overlap with the orthographic projection of the fourth photoelectric sensor on the substrate 201, or the like.

In an exemplary embodiment, as shown in FIG. 6, a length W_{W} of the first channel region in the second direction, a length W_{R} of the second channel region in the second direction, a length W_{G} of the third channel region in the second direction and a length W_{B} of the fourth channel region in the second direction are same, and W_{W}, W_{R}, W_{G} and W_{B} are not separately labeled but are labeled as W in FIG. 6.

FIG. 7 is a cross-sectional view at identification C of the photoelectric sensor assembly shown in FIG. 6. In FIG. 7, the insulation layer 205 is not filled with pattern to facilitate marking. As shown in FIG. 7, a length L_{W} of the first channel region in the first direction, a length L_{R} of the second channel region in the first direction, a length L_{G} of the third channel region in the first direction and a length L_{B} of the fourth channel region in the first direction are the same, and L_{W}, L_{R}, L_{G} and L_{B} are not separately labeled but are labeled as L in FIG. 7.

As shown in FIG. 7, a thickness H_{W} of the first channel region is less than a thickness H_{G} of the third channel region, the thickness H_{G} of the third channel region is less than a thickness H_{R} of the second channel region, and the thickness H_{R} of the second channel region is less than a thickness H_{B} of the fourth channel region.

In an exemplary embodiment, a thickness H_{W} of the first channel region is less than a thickness H_{G} of the third channel region and a thickness H_{R} of the second channel region, and the thickness H_{G} of the third channel region and the thickness H_{R} of the second channel region are less than a thickness H_{B} of the fourth channel region.

As shown in FIG. 7, H_{W}, H_{R}, H_{G} and H_{B} are differentially designed to adjust the photodiode to compensate for the total number of photons of ambient light.

Herein,

$${T}_{W} \times {EQE}_{W} / S ( {H}_{W} ) = {T}_{R} \times {EQE}_{R} / S ( {H}_{R} ) = {T}_{G} \times {EQE}_{G} / S ( {H}_{G} ) = {T}_{B} \times {EQE}_{B} / S ( {H}_{B} ) .$$

T_{W} is transmittance of the light-transmitting pattern and is 100%; T_{R} is transmittance of the first photoresist pattern, T_{R}=∫₃₀₀⁷⁸⁰T_{R}(λ)d_{λ}; T_{G} is transmittance of the second photoresist pattern, T_{G}=∫₃₀₀⁷⁸⁰T_{G}(λ)d_{λ}; T_{B} is transmittance of the third photoresist pattern, T_{B}=∫₃₀₀⁷⁸⁰T_{B}(λ)₈₀; EQE_{W}/S (H_{W}) is a spectral excitation conversion efficiency per unit area of the first channel region with a thickness of H_{W}; EQE_{R}/S (H_{R}) is a spectral excitation conversion efficiency per unit area of the second channel region with a thickness of H_{R}; EQE_{G}/S (H_{G}) is a spectral excitation conversion efficiency per unit area of the third channel region with a thickness of H_{G}; EQE_{B}/S (H_{B}) is a spectral excitation conversion efficiency per unit area of the fourth channel region with a thickness of H_{B}.

In an exemplary embodiment, H_{W}, H_{R}, H_{G} and H_{B} satisfy the following equations: EQE_{W}(H_{W})=EQE_{R}(H_{R})=EQE_{G}(H_{G})=EQE_{B}(H_{B}).

Herein, EQE_{W}(H_{W}) is a spectral excitation conversion efficiency of the first channel region with a thickness of H_{W}; EQE_{R}(H_{R}) is a spectral excitation conversion efficiency of the second channel region with a thickness of H_{R}; EQE_{G}(H_{G}) is a spectral excitation conversion efficiency of the third channel region with a thickness of H_{G}; EQE_{B}(H_{B}) is a spectral excitation conversion efficiency of the fourth channel region with a thickness of H_{B}.

In an exemplary embodiment, taking EQE_{W}(H_{W}) as an example to illustrate a calculating method of EQE_{W}(H_{W}), the photoelectric sensors with different thicknesses of channel regions are selected, and a curve of the thickness of the channel region versus the spectral excitation conversion efficiency is obtained through light irradiation of respective wavelength bands (such as 380 nm to 780 nm). Subsequently, the spectral excitation conversion efficiency of the channel region with the thickness of H_{W}, i.e. EQE_{W}(H_{W}), is obtained from this curve.

FIG. 9 is a curve graph of an output signal intensity of a photoelectric sensor assembly. As shown in FIG. 9, after being irradiated by an integral standard light source, a ratio of output signal intensities (currents) generated by the first photoelectric sensor, the second photoelectric sensor, the third photoelectric sensor and the fourth photoelectric sensor in the existing photoelectric sensor group is 18.3%:16.7%:5.4%:59.5%, which is approximately 3:3:1:11. That is, the output signal intensity generated by the first photoelectric sensor is 11 times that of the fourth photoelectric sensor when the dimensions of the channel regions are the same.

FIG. 10 is a curve graph of an output signal intensity of a photoelectric sensor assembly according to an embodiment of the present disclosure. As shown in FIG. 10, after being irradiated by an integral standard light source and compensated by the photoelectric sensor assembly according to the embodiment of the present disclosure, a ratio of output signal intensities (currents) generated by the first photoelectric sensor, the second photoelectric sensor, the third photoelectric sensor, and the fourth photoelectric sensor in the photoelectric sensor assembly in the embodiment of the present disclosure is 22.2%:24.9%:36.7%:25.4%, and the output signal intensities generated by each photoelectric sensor are relatively close.

In the embodiment of the present disclosure, the signal intensity output by the photoelectric sensor is only illustrated by the current. In an embodiment of the present disclosure, the intensities of the signals output by at least part of the photoelectric sensors in the photoelectric sensor group are substantially the same. For example, a difference between the intensities of the signals output by two photoelectric sensors may be within 30%, and for example, the difference may be within 10%.

An embodiment of the present application provides an electronic device. The electronic device includes the photoelectric sensor assembly described in any of the above embodiments. The electronic device may be any product or component with a display function, such as a display panel, a mobile phone, a tablet computer, a television, a laptop computer, a digital photo frame, or a navigator.

Although the embodiments disclosed in the present disclosure are described as above, the described contents are only embodiments which are adopted in order to facilitate understanding of the present disclosure, and are not intended to limit the present disclosure. It should be noted that the above examples or embodiments are exemplary only but not restrictive. Therefore, the present disclosure is not limited to what is specifically shown and described herein. Various modifications, substitutions or omissions may be made in forms and details of implementations without departing from the scope of the present disclosure.

1. A photoelectric sensor assembly comprising:
a substrate;
at least one photoelectric sensor group located on a side of the substrate; wherein the photoelectric sensor group comprises at least two photoelectric sensors, each photoelectric sensor comprises a channel region, the at least two photoelectric sensors receive light of different colors, and dimensions of channel regions of the at least two photoelectric sensors are different.

2. The photoelectric sensor assembly of claim 1, wherein the photoelectric sensor further comprises a first doped region and a second doped region; the first doped region and the second doped region are located on opposite sides of the channel region in a first direction, and at least one of followings of the channel regions of the at least two photoelectric sensors are different: a length in the first direction, a length in a second direction, and a thickness; and
the first direction is different from the second direction, and a plane formed by the first direction and the second direction is parallel to a plane where the substrate is located.

3. The photoelectric sensor assembly of claim 1, wherein the photoelectric sensor group comprises a first photoelectric sensor that receives a first color light, a second photoelectric sensor that receives a second color light, a third photoelectric sensor that receives a third color light, and a fourth photoelectric sensor that receives a fourth color light; and
the photoelectric sensor assembly further comprises a photoresist layer located on a side of the photoelectric sensor group away from the substrate; the photoresist layer comprises a light-transmitting pattern, a first photoresist pattern, a second photoresist pattern, and a third photoresist pattern; an orthographic projection of the light-transmitting pattern on the substrate overlaps with an orthographic projection of the first photoelectric sensor on the substrate, an orthographic projection of the first photoresist pattern on the substrate overlaps with an orthographic projection of the second photoelectric sensor on the substrate, an orthographic projection of the second photoresist pattern on the substrate overlaps with an orthographic projection of the third photoelectric sensor on the substrate, an orthographic projection of the third photoresist pattern on the substrate overlaps with an orthographic projection of the fourth photoelectric sensor on the substrate; and the first color light is a light transmitted through a full visible light wavelength band, the second color light is a light transmitted through the first photoresist pattern, the third color light is a light transmitted through the second photoresist pattern, and the fourth color light is a light transmitted through the third photoresist pattern.

4. The photoelectric sensor assembly of claim 3, wherein the first photoelectric sensor comprises a first channel region, the second photoelectric sensor comprises a second channel region, the third photoelectric sensor comprises a third channel region, the fourth photoelectric sensor comprises a fourth channel region; a thickness H_{W} of the first channel region, a thickness H_{R} of the second channel region, a thickness H_{G} of the third channel region and a thickness H_{B} of the fourth channel region are the same; a length L_{W} of the first channel region in a first direction, a length L_{R} of the second channel region in the first direction, a length L_{G} of the third channel region in the first direction, and a length L_{B} of the fourth channel region in the first direction are the same; and at least two of a length W_{W} of the first channel region in a second direction, a length W_{R} of the second channel region in the second direction, a length W_{G} of the third channel region in the second direction, and a length W_{B} of the fourth channel region in the second direction are different.

5. The photoelectric sensor assembly of claim 4, wherein following equations are satisfied: W_{W}×T_{W}×EQE_{W}/S=W_{R}×T_{R}×EQE_{R}/S=W_{G}×T_{G}×EQE_{G}/S=W_{B}×T_{B}×EQE_{B}/S; and
wherein T_{W} is transmittance of the light-transmitting pattern, T_{R} is transmittance of the first photoresist pattern, T_{G} is transmittance of the second photoresist pattern, T_{B} is transmittance of the third photoresist pattern, EQE_{W}/S is a spectral excitation conversion efficiency per unit area of the first channel region, EQE_{R}/S is a spectral excitation conversion efficiency per unit area of the second channel region, EQE_{G}/S is a spectral excitation conversion efficiency per unit area of the third channel region, and EQE_{B}/S is a spectral excitation conversion efficiency per unit area of the fourth channel region.

6. The photoelectric sensor assembly of claim 4, wherein following equations are satisfied: W_{W}×EQE_{W}=W_{R}×EQE_{R}=W_{G}×EQE_{G}=W_{B}×EQE_{B}; and
wherein EQE_{W} is a spectral excitation conversion efficiency of the first channel region, EQE_{R} is a spectral excitation conversion efficiency of the second channel region, EQE_{G} is a spectral excitation conversion efficiency of the third channel region; and EQE_{B} is a spectral excitation conversion efficiency of the fourth channel region.

7. The photoelectric sensor assembly of claim 3, wherein the first photoelectric sensor comprises a first channel region, the second photoelectric sensor comprises a second channel region, the third photoelectric sensor comprises a third channel region, and the fourth photoelectric sensor comprises a fourth channel region; a length L_{W} of the first channel region in a first direction, a length L_{R} of the second channel region in the first direction, a length L_{G} of the third channel region in the first direction and a length L_{B} of the fourth channel region in the first direction are the same; a length W_{W} of the first channel region in a second direction, a length W_{R} of the second channel region in the second direction, a length W_{G} of the third channel region in the second direction, and a length W_{B} of the fourth channel region in the second direction are the same; at least two of a thickness H_{W} of the first channel region, a thickness H_{R} of the second channel region, a thickness H_{G} of the third channel region and a thickness H_{B} of the fourth channel region are different.

8. The photoelectric sensor assembly of claim 7, wherein following equations are satisfied: T_{W}×EQE_{W}/S(H_{W})=T_{R}×EQE_{R}/S(H_{R})=T_{G}×EQE_{G}/S(H_{G})=T_{B}×EQE_{B}/S(H_{B}); and
wherein T_{W} is transmittance of the light-transmitting pattern, T_{R} is transmittance of the first photoresist pattern, T_{G} is transmittance of the second photoresist pattern, T_{B} is transmittance of the third photoresist pattern, EQE_{W}/S(H_{W}) is a spectral excitation conversion efficiency per unit area of the first channel region with a thickness of H_{W}; EQE_{R}/S(H_{R}) is a spectral excitation conversion efficiency per unit area of the second channel region with a thickness of H_{R}; EQE_{G}/S(H_{G}) is a spectral excitation conversion efficiency per unit area of the third channel region with a thickness of H_{G}; and EQE_{B}/S(H_{B}) is a spectral excitation conversion efficiency per unit area of the fourth channel region a thickness of H_{B}.

9. The photoelectric sensor assembly of claim 7, wherein following equations are satisfied: EQE_{W}(H_{W})=EQE_{R}(H_{R})=EQE_{G}(H_{G})=EQE_{B}(H_{B}); and
wherein EQE_{W}(H_{W}) is a spectral excitation conversion efficiency of the first channel region with a thickness of H_{W}; EQE_{R}(H_{R}) is a spectral excitation conversion efficiency of the second channel region with a thickness of H_{R}; EQE_{G}(H_{G}) is a spectral excitation conversion efficiency of the third channel region with a thickness of H_{G}; and EQE_{B}(H_{B}) is a spectral excitation conversion efficiency of the fourth channel region with a thickness of H_{B}.

10. The photoelectric sensor assembly of claim 2, wherein the photoelectric sensor assembly further comprises a first electrode and a second electrode located on a side of the photoelectric sensor away from the substrate, the first electrode is connected to the first doped region, and the second electrode is connected to the second doped region.

11. The photoelectric sensor assembly of claim 3, wherein the photoelectric sensor assembly further comprises an insulation layer located between the channel region and the photoresist layer.

12. An electronic device comprising the photoelectric sensor assembly of claim 1.

13. An electronic device comprising the photoelectric sensor assembly of claim 2.

14. An electronic device comprising the photoelectric sensor assembly of claim 3.

15. An electronic device comprising the photoelectric sensor assembly of claim 4.

16. An electronic device comprising the photoelectric sensor assembly of claim 5.

17. An electronic device comprising the photoelectric sensor assembly of claim 6.

18. An electronic device comprising the photoelectric sensor assembly of claim 7.

19. An electronic device comprising the photoelectric sensor assembly of claim 8.

20. An electronic device comprising the photoelectric sensor assembly of claim 9.
